(19) United States
(12) Patent Application Publication
(10) Pub. No.: US 2003/0237037 A1
(43) Pub. Date: Dec. 25, 2003

(54) Determination of signal transmission accuracy of a wireless device

(75) Inventor: Aravind Soundararajan, Ossining, NY (US)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V.

(21) Appl. No.: 10/175,196

(22) Filed: Jun. 19, 2002

(51) Int. Cl. H04L 1/00; G06F 11/00; G06F 11/30; H03M 13/00; G08C 25/00; H04L 1/18; G08C 25/02

(52) U.S. Cl. 714/748

(57) ABSTRACT

A method and system for ascertaining the accuracy of transmission of a test signal. A first transceiver device transmits the test signal to a second transceiver device. The first transceiver device is wireless. The second transceiver device receives and retransmits the test signal back to the first transceiver device, without manual intervention by a user of the second transceiver device. The first transceiver device may additionally determine a measure of an extent to which the retransmitted signal differs from the test signal, and display the measure so determined.

### BACKGROUND OF THE INVENTION

1. Technical Field

The present invention relates to a method and system for determining the transmission accuracy of a test signal transmitted to a remote device by a wireless transmitting device.

2. Related Art

When a first person using a Walkie-Talkie talks to a second person also using a Walkie-Talkie, the first person does not know how accurate the transmission is from the Walkie-Talkie of the first person to the Walkie-Talkie of the second person. Thus, there is a need for a method and system for overcoming the lack of knowledge by the first person as to how accurate the transmission is from the Walkie-Talkie of the first person to the Walkie-Talkie of the second person.

### Summary of the Invention

In first embodiments, the present invention provides a method for ascertaining the accuracy of transmission of a test signal, comprising:

transmitting by a first transceiver device the test signal to a second transceiver device, wherein the first transceiver device is wireless; and

receiving by the first transceiver device a return signal from the second transceiver device, wherein the return signal is the test signal as retransmitted by the second transceiver device to the first transceiver device after having been received by the second transceiver device, and wherein the receipt and retransmission of the test signal by the second transceiver device is accomplished without manual intervention by a user of the second transceiver device.

In second embodiments, the present invention provides a method for retransmitting a test signal, comprising:

receiving by a second transceiver device the test signal that had been transmitted to the second transceiver device by a first transceiver device, wherein the first transceiver device is wireless; and

retransmitting by the second transceiver device the test signal to the first transceiver device without manual intervention by a user of the second transceiver device.

In third embodiments, the present invention provides a system for ascertaining the accuracy of transmission of a test signal, comprising a first transceiver device, wherein the first transceiver device is wireless, and wherein the first transceiver device is adapted to:

transmit the test signal to a second transceiver device; and

receive a return signal from the second transceiver device, wherein the return signal is the test signal as retransmitted by the second transceiver device to the first transceiver device after having been received by the second transceiver device, and wherein the receipt and retransmission of the test signal by the second transceiver device is accomplished without manual intervention by a user of the second transceiver device.

In fourth embodiments, the present invention provides a system for retransmitting a test signal, comprising a second transceiver device adapted to:

receive the test signal transmitted to the second transceiver device by a first transceiver device, wherein the first transceiver device is wireless; and

retransmit the test signal to the first transceiver device without manual intervention by a user of the second transceiver device.

The present invention provides a method and system for overcoming the lack of knowledge by a first person as to how accurate transmission is from a Walkie-Talkie of the first person to a Walkie-Talkie of a second person.

### BRIEF DESCRIPTION OF THE DRAWINGS

FIG. 1 depicts a system comprising a first transceiver device in communication with a second transceiver device, in accordance with embodiments of the present invention.

FIG. 2 depicts the first transceiver device of FIG. 1, in accordance with embodiments of the present invention.

FIG. 3 depicts the second transceiver device of FIG. 1, in accordance with embodiments of the present invention.

FIG. 4 depicts a flow chart for a method by which the first transceiver device of FIG. 1 transmits a test signal to the second transceiver device of FIG. 1 and receives a return signal from the second transceiver device, in accordance with embodiments of the present invention.

FIG. 5 depicts a flow chart for a method by which the second transceiver device of FIG. 1 receives a test signal from the first transceiver device of FIG. 1 and transmits a return signal to the first transceiver device, in accordance with embodiments of the present invention.

### DETAILED DESCRIPTION OF THE INVENTION

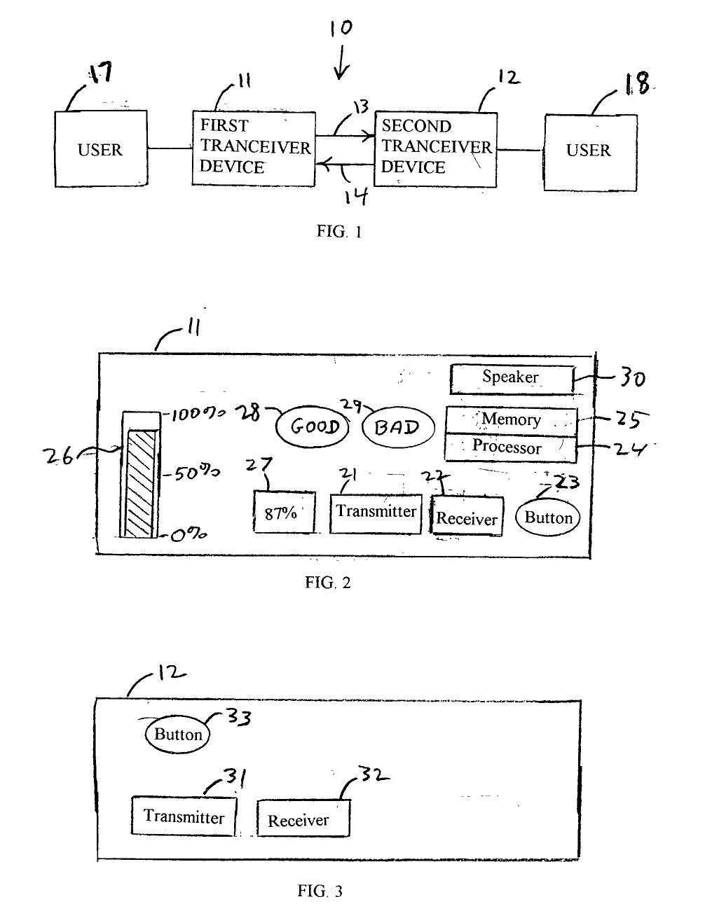

FIG. 1 depicts a system 10 comprising a first transceiver device 11 in communication with a second transceiver device 12, in accordance with embodiments of the present invention. A transceiver device is defined herein as a device capable of both transmitting and receiving a signal such as an analog signal (i.e., a sequence of frequency tones) or a digital signal (i.e., a bit pattern). The signal may be an electromagnetic signal such as in the radio frequency range or in any other frequency range that can be used in wireless communication between two transceiver devices. The first transceiver device 11 is wireless. The second transceiver device 12 may be wireless or may not be wireless. Regardless of whether the second transceiver device 12 is a wireless device, the communication of signals between the first transceiver device 11 and the second transceiver device 12 is a wireless communication in both directions (i.e., from the first transceiver device 11 to the second transceiver device 12, or from the second transceiver device 12 to the first transceiver device 11). An example of a transceiver device which may be used in the present invention is a Walkie Talkie, which is a wireless device. Another example of a transceiver device which may be used in the present invention is a printer that includes both a receiver and a transmitter such that the printer may communicate with a remote Personal Digital Assistant (PDA) via its receiver and transmitter. Note that the printer is not wireless if the printer is powered by a voltage source via electrical wiring that couples the printer to the voltage source. Nonetheless, the printer may engage in wireless communication with the PDA.

A user 17 may be coupled to the first transceiver device 11. For example, the user 17 may be operating or using the first transceiver device 11. A user 18 may be coupled to the second transceiver device 11. For example, the user 18 may be operating or using the second transceiver device 12. A transceiver device does not necessarily require the presence of a user while in operation. In some embodiments of the present invention, both users 17 and 18 are present to operate the first and second first transceiver devices 11 and 12, respectively (e.g., in an application in which the first transceiver device 11 is a Walkie Talkie and the second transceiver device 12 is also a Walkie Talkie). In other embodiments of the present invention, the user 17 is present to operate the first transceiver device 11 and the second transceiver device 12 may operate without a user (e.g., in an application in which the first transceiver device 11 is a PDA and the second transceiver device 12 is a printer that comprises a transmitter and a receiver).

FIG. 2 depicts the first transceiver device 11 of FIG. 1, in accordance with embodiments of the present invention. The first transceiver device 11 comprises a transmitter 21, a receiver, 22, a button 23, a processor 24, and a memory 25. The first transceiver device 11 may additionally comprise one or more display units such as visual display unit (e.g., meter 26, digital display 27, lights 28 and 29) or an audio display unit (e.g., speaker 30).

FIG. 3 depicts the second transceiver device 12 of FIG. 1, in accordance with embodiments of the present invention. The second transceiver device 12 comprises a transmitter 31, a receiver, 32, and a button 33.

In FIGS. 1-3, the first transceiver device 11 is transmitting signals via the transmitter 21 to the second transceiver device 12, and the second transceiver device 12 is receiving the signals from the first transceiver device 11 via the receiver 32. However, the user 17 of the first transceiver device 11 may recognize that there is a possibility that said signals received by the second transceiver device 12 may not be identical to said signals transmitted by the first transceiver device 11, because of signal distortions. For example, if the signals are digital signals comprising bit patterns, then such signal distortions may comprise dropped bits, added bits (e.g., due to noise), changed bits, etc. Due to the possibility of signal distortion, the user 17 may desire to know how accurately such signals are being received by the second transceiver device 12. The present invention enables the user 17 to obtain an indication of the extent to which the signals received by the second transceiver device 12 are the same (or different) as the corresponding signals sent by the first transceiver device 11.

To test the accuracy of its signal transmissions, the user 17 may cause the transmitter 21 of the first transceiver device 11 to transmit a test signal 13 to the second transceiver device 12 where the test signal 13 may be received at the receiver 32. The test signal 13 may be an analog signal (i.e., a sequence of frequency tones) or a digital signal (i.e., a bit pattern). Any suitable modulation scheme may be used by the first transceiver device 11 to transmit the test signal 13 to the second transceiver device 12. The test signal 13 may be a predetermined signal who content and form is or is not a priori known to the second transceiver device 12, or the test signal may be dynamically generated as a known function of predetermined variables (e.g., the estimated distance between the first transceiver device 11 and the second transceiver device 12), or the test signal may be dynamically generated as having a random aspect through use of a random number generator in the first transceiver device 11.

The user 17 may activate sending the test signal 13 by pressing the button 23 to activate a test mode in the first transceiver device 11, or by any other activation method known in the art as an alternative to pressing the button 23. The test mode so activated enables the transmitting of the test signal 13 by the first transceiver device 11, and also enables receipt of a return signal 14 from the second transceiver device 12 as will be described infra. Said activation of the test mode further enables computation and display of an error E associated with the return signal 14 as will be described infra.

After receiving the test signal 13, the second transceiver device 12 transmits the return signal 14, via the transmitter 31, to the first transceiver device 11 where the return signal 14 may be received at the receiver 22. The return signal 14 is the test signal 13 as received and retransmitted by the second transceiver device 12. Thus, transmission of the return signal 14 is effectively a retransmission of the test signal 13 back to the first transceiver device 11. Said receipt and retransmission of the test signal 13 by the second transceiver device 12 may be accomplished automatically without manual intervention by the user 18 of the second transceiver device 12, if prior to said receipt of the test signal 13 the second transceiver device 12 had been placed in a test mode that enables said receiving and retransmitting by the second transceiver device 12. The test mode in the second transceiver device 12 may be activated by pressing the button 33, or by any other activation method known in the art as an alternative to pressing the button 33. Additionally if the content and form of the test signal 13 is a priori known to the second transceiver device 12, then the test mode in the second transceiver device 12 may be activated by detection of the test signal 13 based on testing signals received from the first transceiver device 11 against the a priori known content and form of the test signal 13. As another alternative, the second transceiver device 12 could be hardwired to always be in the test mode.

After receiving the return signal 14, the first transceiver device 11 determines (i.e., computes) a measure of an “error” in the return signal 14, wherein the error denotes an extent to which the return signal 14 differs from the test signal 13. The error may be defined mathematically in various alternative ways as is known by a person of ordinary skill in the art, and this patent discloses next, for illustrative purposes only, examples of how said error may be defined and computed.

If the test signal 13 (and the return signal 14) is an analog signal with A_{TEST}(t) denoting the amplitude of the test signal 13 as a function of time t, and with A_{RETURN}(t) denoting the amplitude of the return signal 14 as a function of time t, then the error E may be computed as:

E=|(∫A_{RETURN}(t)dt—∫A_{TEST}(t)dt)/∫A_{TEST}(t)dt)| (1)

In Equation (1), the integrals are evaluated over the time interval during which the signals A_{TEST}(t) and A_{RETURN}(t) exist. The error E in Equation (1) may be converted to a percent by multiplying E by 100.

If the test signal 13 (and the return signal 14) is a digital signal, then the error E may be computed as:

E=N_{ERROR}/N_{TOTAL} (2)

In Equation (2), N_{ERROR} is the number of error bits in the return signal 14 and N_{TOTAL} is the total number of bits in the test signal 13. An error bit is a lost bit, an added bit, or a changed bit. An error bit actually exists in the return signal 14 if the error bit is an added bit or a changed bit. An error bit does not actually exist in the return signal 14 if the error bit is a lost bit. The error E in Equation (2) may be converted to a percent by multiplying E by 100.

The analysis of the test signal 13 and the return signal 14, and the computation of the error E, is performed in the first transceiver device 11 by execution of code by a processor 24, wherein the code is stored in a memory 25. The memory may be any type of memory known by a person of ordinary skill in te art such as a volatile memory (e.g., read-only memory (ROM)) or a non-volatile memory (dynamic random access memory (DRAM)) or both. The executable code may be hard-wired into non-volatile memory or may be accessible through a built-in mini-storage device such as a mini-tape unit within the first transceiver device 11.

After the error is computed, the first transceiver device 11 may display the error E in any way that would be known by a person of ordinary skill in the art, such as in the following non-limiting examples, wherein said displaying of the error E is implemented by execution of code by the processor 24. A first example of how the error E may be displayed is through use of a meter 26. In FIG. 2, the meter 26 shows a bar whose extent (i.e., height) denotes the error E as a percent. A second example of how the error E may be displayed is through use of a digital display 27 (e.g., a light emitting diode (LED)), which displays the error as “87%” in FIG. 2.

A third example of how the error E may be displayed is through use of lightable areas 28 and 29 which may “turned on” in various ways such as lighting up, flashing, etc. If lightable area 28 is turned on then the transmission of the test signal 13 is “good” (i.e., the error E is below a maximum permissible error E_{MAX}), whereas lightable area 29 is turned on when the transmission of the test signal 13 is “bad” (i.e., the error E is not below E_{MAX}). The maximum permissible error E_{MAX} may be hardwired in some embodiments or may be user-selectable or user-inputable in other embodiments. While FIG. 3 shows only two lightable areas 28 and 29, the first transceiver device 11 may have any number of lightable areas. For example, three lightable areas may be used to discriminate between a clearly good transmission, a clearly bad transmission, and a marginal transmission that is barely acceptable. If N lightable areas are present (N>2) then N−1 error division values must be utilized to determine which of the N lightable areas the error E falls within. The N−1 error division values may be hardwired in some embodiments or may be user-selectable or user-inputable in other embodiments.

A fourth example of how the error E may be displayed is through use of an audio display such as through use of the speaker 30 or a bell, chime, etc. An audio display is analogous to the visual display afforded by the lightable areas (e.g., lightable areas 28 and 29) described supra. For example, words or sounds may be expressed through the speaker 30, wherein different words or sounds denote different domains (e.g., a “good” domain, a “bad” domain, etc.) of the error E. If a bell or chime is used, different sounds or tones denote different domains of the error E.

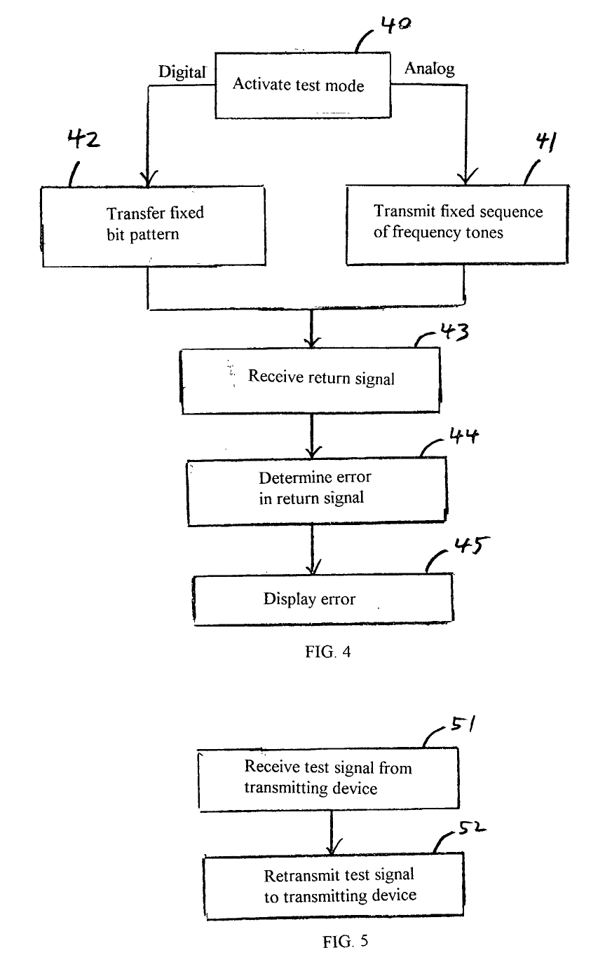

FIG. 4 depicts a flow chart for a method by which the first transceiver device 11 of FIG. 1 transmits the test signal 13 to the second transceiver device 12 of FIG. 1 and receives the return signal 14 from the second transceiver device 12, in accordance with embodiments of the present invention. Step 41 activates the test mode in the first transceiver device 11 such as by pressing the button 23 as described supra in conjunction with FIG. 2. Activating the test mode initiates transmitting the test signal 13 as either an analog signal or a digital signal. If an analog signal is to be transmitted then a fixed sequence of frequency tones is transmitted in step 41, but if a digital signal is to be transmitted then a fixed bit pattern is instead transmitted in step 42. After the second transceiver device 12 receives the test signal 13 and retransmits the test signal 13 as the return signal 14, the first transceiver device 11 receives the return signal 14 in step 43. Then the first transceiver device 11 determines the error E in the return signal 14 (relative to the test signal 13 as described supra) in step 44. The first transceiver device 11 displays the error E in step 45.

FIG. 5 depicts a flow chart for a method by which the second transceiver device 12 of FIG. 1 receives the test signal 13 from the first transceiver device 11 of FIG. 1 and transmits the return signal 14 to the first transceiver device 11, in accordance with embodiments of the present invention. In step 51, the second transceiver device 12 receives the test signal 13 from the first transceiver device 11. In step 52, the second transceiver device 12 retransmits the test signal 13, as the return signal 14, to the first transceiver device 11. FIG. 5 assumes that the second transceiver device 12 is in the test mode during execution of steps 51 and 52.

The second transceiver device 12 could be similar to, or identical with, the first transceiver device 11, inasmuch as the second transceiver device 12 could transmit a test signal to a third tranceiver device and receive a return signal from the third tranceiver device in the same manner as has been described supra for the the first transceiver device 11.

While embodiments of the present invention have been described herein for purposes of illustration, many modifications and changes will become apparent to those skilled in the art. Accordingly, the appended claims are intended to encompass all such modifications and changes as fall within the true spirit and scope of this invention.

What is claimed is:

1. A method for ascertaining the accuracy of transmission of a test signal, comprising:
transmitting by a first transceiver device the test signal to a second transceiver device, wherein the first transceiver device is wireless; and
receiving by the first transceiver device a return signal from the second transceiver device, wherein the return signal is the test signal as retransmitted by the second transceiver device to the first transceiver device after having been received by the second transceiver device, and wherein the receipt and retransmission of the test signal by the second transceiver device is accomplished without manual intervention by a user of the second transceiver device.

2. The method of claim 1, further comprising prior to said transmitting by the first transceiver device: activating a test mode in the first transceiver device such that the test mode enables said transmitting and receiving by the first transceiver device.

3. The method of claim 1, further comprising after said receiving by the first transceiver device:
determining by the first transceiver device a measure of an extent to which the return signal differs from the test signal; and
displaying by the first transceiver device the measure so determined.

4. The method of claim 3, further comprising prior to said transmitting by the first transceiver device: activating a test mode in the first transceiver device such that the test mode enables said transmitting, receiving, determining, and displaying by the first transceiver device.

5. The method of claim 1, wherein the test signal is an analog signal.

6. The method of claim 1, wherein the test signal is a digital signal.

7. The method of claim 1, wherein the second transceiver device is wireless.

8. The method of claim 1, wherein the second transceiver device is not wireless.

9. A method for retransmitting a test signal, comprising:
receiving by a second transceiver device the test signal that had been transmitted to the second transceiver device by a first transceiver device, wherein the first transceiver device is wireless; and
retransmitting by the second transceiver device the test signal to the first transceiver device without manual intervention by a user of the second transceiver device.

10. The method of claim 9, further comprising prior to said receiving by the second transceiver device: activating a test mode in the second transceiver device such that the test mode enables said receiving and retransmitting by the second transceiver device.

11. The method of claim 9, wherein the test signal is an analog signal.

12. The method of claim 9, wherein the test signal is a digital signal.

13. The method of claim 9, wherein the second transceiver device is wireless.

14. The method of claim 9, wherein the second transceiver device is not wireless.

15. A system for ascertaining the accuracy of transmission of a test signal, comprising a first transceiver device, wherein the first transceiver device is wireless, and wherein the first transceiver device is adapted to:
transmit the test signal to a second transceiver device; and
receive a return signal from the second transceiver device, wherein the return signal is the test signal as retransmitted by the second transceiver device to the first transceiver device after having been received by the second transceiver device, and wherein the receipt and retransmission of the test signal by the second transceiver device is accomplished without manual intervention by a user of the second transceiver device.

16. The system of claim 15, wherein the first transceiver device comprises a test mode adapted to be activated so as to enable said transmission of the test signal and receipt of the return signal.

17. The system of claim 15, wherein the first transceiver device is further adapted to:
determine a measure of an extent to which the return signal differs from the test signal; and
display the measure so determined.

18. The system of claim 15, wherein the first transceiver device comprises a test mode adapted to be activated so as to enable said: transmission of the test signal, receipt of the return signal, determination of the measure, and display of the measure.

19. The system of claim 14, wherein the test signal is an analog signal.

20. The system of claim 14, wherein the test signal is a digital signal.

21. The system of claim 14, wherein the second transceiver device is wireless.

22. The system of claim 14, wherein the second transceiver device is not wireless.

23. A system for retransmitting a test signal, comprising a second transceiver device adapted to:
receive the test signal transmitted to the second transceiver device by a first transceiver device, wherein the first transceiver device is wireless; and
retransmit the test signal to the first transceiver device without manual intervention by a user of the second transceiver device.

24. The system of claim 23, wherein the second transceiver device comprises a test mode adapted to be activated so as to enable said receipt and retransmission of the test signal by the second transceiver device.

25. The system of claim 23, wherein the test signal is an analog signal.

26. The system of claim 23, wherein the test signal is a digital signal.

27. The system of claim 23, wherein the second transceiver device is wireless.

28. The system of claim 23, wherein the second transceiver device is not wireless.
